(19) United States
(12) Patent Application Publication
(10) Pub. No.: US 2007/0001738 A1
(43) Pub. Date: Jan. 4, 2007

(54) Variable resistance circuit

(76) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(21) Appl. No.: 11/416,771

(22) Filed: May 3, 2006

(30) Foreign Application Priority Data
Jun. 30, 2005 (JP) JP 2005-192386

(51) Int. Cl. H03L 5/00

(52) U.S. Cl. 327/308

(57) ABSTRACT

A variable resistance circuit includes a PIN diode circuit which adjusts an RF resistance for PIN diodes according to a control voltage, a first means which level-shifts one control voltage by a level shift circuit and applies a non-linear characteristic to the so level-shifted control voltage using a zener diode characteristic by a zener diode circuit, a second means which applies a voltage offset to the other control voltage by a weighting circuit, and an adding circuit which adds respective output voltages of the first means and the second means. When the output of the adding circuit is applied to the PIN diode circuit, the shift voltage of the level shift circuit, the zener characteristic of the zener diode circuit and the voltage offset of the weighting circuit are selected and adjusted to set the value of the RF resistance of the PIN diode circuit so as to change substantially linearly with respect to a change in control voltage.

### RELATED/PRIORITY APPLICATION

This application claims priority with respect to Japanese Application No. 2005-192386, filed Jun. 30, 2005.

### BACKGROUND OF THE INVENTION

1. Field of the Invention

The present invention relates to a variable resistance circuit, and particularly to a variable resistance circuit wherein a control voltage compensating circuit is connected to the input side of a PIN diode circuit constituted of PIN diodes, and a change in high frequency or RF resistance with respect to an input control voltage of the PIN diode circuit is set linear by the control voltage compensating circuit.

2. Description of the Related Art

Generally, a variable resistance circuit which has variable control resistive elements and controls a voltage or current supplied to each of the variable control resistive elements to thereby change the resistance value of each variable resistive element, has been widely used in a variable attenuator, a voltage-controlled oscillator, etc. As the variable control resistive elements used in such a variable resistance circuit, diodes are normally used. Particularly when used in a high-frequency region or domain, ones such as PIN diodes or the like are used wherein a high frequency or RF resistance changes.

Meanwhile, a change in RF resistance is relatively large in the PIN diode. As one example thereof, a PIN diode HVM14 manufactured by the H company has a characteristic in which when its forward current is 10 mA, a high frequency or RF resistance thereof is about 2.5Ω, whereas when the forward current is reduced to 1 μA, the RF resistance is increased to about 6 KΩ. The current-resistance characteristic indicated by the PIN diode has a relationship in which when the relationship between the value of the forward current and the value of the RF resistance is expressed in graph on a double logarithmic scale assuming that the horizontal axis is set to the forward current value and the vertical axis is set to the RF resistance value, the graph becomes close to a substantially upward straight line. Of course, the present current-resistance characteristic is indicated by the above PIN diode and shows the relationship that falls outside the relationship in which the graph is close to the straight line, depending upon the type of diode, the kind thereof, etc.

A high frequency or RF resistance of a general diode as well as a PIN diode is determined based on one obtained by synthesizing a PN-junction resistance, a PN-junction capacitance, a diffusion resistance, a lead-wire inductance and a line-to-line capacitance or the like. When a given amount of current is caused to flow into a diode, its RF resistance value normally becomes considerably smaller than its DC resistance value. In the above-described PIN diode HVM14, for example, a DC resistance value thereof is about 84Ω (internal voltage drop of the diode at this time is about 0.84V) when an RF resistance value thereof is about 2.5Ω, whereas when the RF resistance value is about 6 KΩ, the DC resistance value is about 400 KΩ (internal voltage drop of the diode at this time is about 0.4V). This shows that since the RF resistance value increases from 2.5Ω to 6 KΩ when a DC voltage applied to the PIN diode is reduced from 0.84V to 0.4V, the RF resistance can be changed to about 2400 times depending on a slight change in the applied voltage, like 0.44V. This means that when, for example, the RF resistance value is set by a manual operation, a predetermined RF resistance value cannot be obtained unless the manual operation is performed critically.

Therefore, in a variable resistance circuit using PIN diodes, it has been normally practiced to connect a plurality of the PIN diodes in series to extend a variable range of a high frequency or RF resistance with a change in applied voltage, and/or to connect resistors in parallel with the PIN diodes to divert a current flowing through the PIN diodes, thereby apparently reducing current sensitivity of each PIN diode. However, such a means as to connect the PIN diodes in series in plural form merely shows that a curve indicative of an applied current vs. RF resistance is enlarged on the whole. A relative characteristic relationship between a high resistance portion indicative of an applied current vs. RF resistance characteristic relatively close to a straight line, and a low resistance portion indicative of an applied current vs. RF resistance characteristic near a curve remains unchanged. Such a means as to connect the parallel resistors to the PIN diodes shows that the range of a change in resistance value of each PIN diode becomes eventually narrow with the connection of the parallel resistors. Both means cannot expect improvement effects so much either.

### SUMMARY OF THE INVENTION

The present invention has been made in view of such a background art. An object of the present invention is to provide a variable resistance circuit wherein a control voltage compensating circuit is connected to a PIN diode circuit to allow a relationship of a change in RF resistance for each PIN diode with respect to a change in input control voltage to become approximately linear, thereby making it easy to adjust the RF resistance.

In order to attain the above object, the present invention provides a variable resistance circuit equipped with means which comprises a PIN diode circuit which adjusts a resistance value for PIN diodes according to the supply of a control voltage, a voltage shift circuit which adds a shift voltage to the control voltage, a zener diode circuit which applies a non-linear characteristic to a voltage outputted from the voltage shift circuit, using a zener characteristic of a zener diode, a weighting circuit which applies a voltage offset to the control voltage, and an adding circuit which adds respective voltages outputted from the zener diode circuit and the weighting circuit and supplies the so-added voltage to the PIN diode circuit; and wherein the shift voltage of the voltage shift circuit, the zener characteristic of the zener diode in the zener diode circuit and the voltage offset value of the weighting circuit are respectively selected and adjusted to set the RF resistance value for the PIN diodes in the PIN diode circuit so as to change approximately linearly with respect to a change in the control voltage.

In this case, the PIN diode circuit in the means is equipped with first constituting means equivalent to one having a configuration in which a first PIN diode used as a series element and a second PIN diode used as a shunt element are reversely L-connected to the same polarity.

The voltage shift circuit in the means is equipped with second constituting means equivalent to one having a configuration in which a first resistor used as a series element and a second resistor used as a shunt element are reversely L-connected and a bias power supply is series-connected to the second resistor.

Further, the zener diode circuit in the means is equipped with third constituting means equivalent to one having a configuration in which a zener diode used as a series element and a resistor used as a shunt element are reversely L-connected.

The adding circuit in the means is equipped with fourth constituting means equivalent to one provided with adding resistors and an amplifier.

According to the variable resistance circuit of the present invention as described above, advantageous effects are brought about in that a voltage shift circuit which adds a shift voltage to a control voltage, a zener diode circuit which applies a non-linear characteristic to a voltage outputted from the voltage shift circuit, using a zener characteristic of a zener diode, a weighting circuit which applies a voltage offset to the control voltage, and an adding circuit which adds respective voltages outputted from the zener diode circuit and the weighting circuit and supplies the so-added voltage to the PIN diode circuit, are connected to the input side of a PIN diode circuit, and the shift voltage of the voltage shift circuit, the zener characteristic of the zener diode in the zener diode circuit and the voltage offset value of the weighting circuit are respectively selected and adjusted, thereby allowing a relationship of a control voltage vs. RF resistance in each PIN diode of the PIN diode circuit to become approximately linear, whereby the value of the RF resistance for the PIN diodes can be made almost exactly inversely-proportional to an apparent change in control voltage, and the RF resistance for the PIN diodes can easily be set to a desired value by adjusting the control voltage by a manual operation.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 shows an embodiment of a variable resistance circuit according to the present invention and is a circuit diagram showing its essential configuration;

FIG. 2 is a characteristic diagram showing, on a linear scale, the relationship between a PIN diode circuit driving voltage, a control voltage Vc and a high-frequency resistor Rf that a PIN diode circuit shown in FIG. 1 assumes;

FIG. 3 is a characteristic diagram illustrating a voltage conversion state at a control voltage compensating circuit when voltage compensation for the PIN diode circuit is performed;

FIG. 4 is a circuit diagram depicting one example illustrative of suitable constants used for various constituent elements in the variable resistance circuit shown in FIG. 1; and

FIG. 5 is a characteristic diagram showing the result of simulation run using the circuit diagram shown in FIG. 4.

### DETAILED DESCRIPTION OF THE PREFERRED EMBODIMENTS

A preferred embodiment of the present invention will be explained hereinafter with reference to the accompanying drawings.

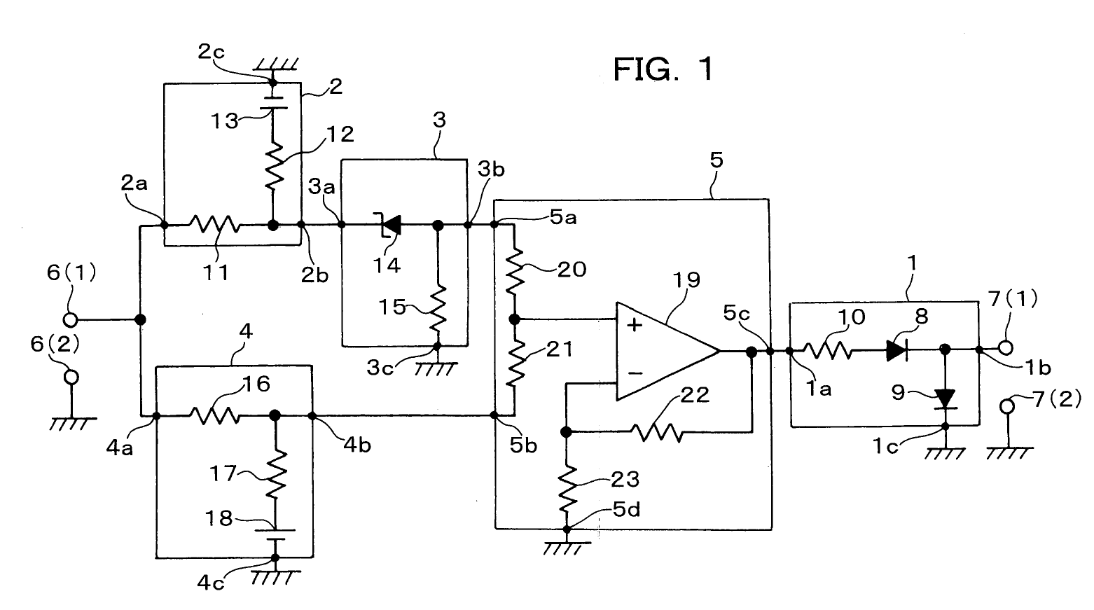

FIG. 1 shows an embodiment of a variable resistance circuit according to the present invention and is a circuit diagram illustrating its essential configuration.

As shown in FIG. 1, the variable resistance circuit according to the present embodiment comprises a PIN diode circuit 1, a voltage shift circuit 2, a zener diode circuit 3, a weighting circuit 4, an adding circuit 5, control voltage input terminals 6(1) and 6(2) and high-frequency or RF resistance output terminals 7(1) and 7(2). A circuit section comprising the voltage shift circuit 2, the zener diode circuit 3, the weighting circuit 4 and the adding circuit 5 constitutes a control voltage compensating circuit. In this case, the PIN diode circuit 1 has an input terminal 1a, an output terminal 1b and a ground terminal 1c and is equipped with a first PIN diode 8, a second PIN diode 9 and a protection resistor 10. The voltage shift circuit 2 is provided with an input terminal 2a, an output terminal 2b and a ground terminal 2c, and a first resistor 11, a second resistor 12 and a bias power supply or battery 13. The zener diode circuit 3 has an input terminal 3a, an output terminal 3b and a ground terminal 3c and is provided with a zener diode 14 and a shunt resistor 15. The weighting circuit 4 has an input terminal 4a, an output terminal 4b and a ground terminal 4c and is provided with a first resistor 16, a second resistor 17 and a bias power supply or battery 18. The adding circuit 5 has a first input terminal 5a, a second input terminal 5b, an output terminal 5c and a ground terminal 5d, and is provided with an amplifier 19, a first adding resistor 20, a second adding resistor 21, a first feedback resistor 22 and a second feedback resistor 23.

The control voltage input terminal 6(1) is connected to the input terminal 2a of the voltage shift circuit 2 and the input terminal 4a of the weighting circuit 4 respectively. The control voltage input terminal 6(2) is connected to ground. The output terminal 2b of the voltage shift circuit 2 is connected to the input terminal 3a of the zener diode circuit 3, whereas the output terminal 3b of the zener diode circuit 3 is connected to the first input terminal 5a of the adding circuit 5. The output terminal 4b of the weighting circuit 4 is connected to the second input terminal 5b of the adding circuit 5, whereas the output terminal 5b of the adding circuit 5 is connected to the input terminal 1a of the PIN diode circuit 1. The RF resistance output terminal 7(1) is connected to the output terminal 1b of the PIN diode circuit 1, whereas the RF resistance output terminal 7(2) is connected to ground.

In the PIN diode circuit 1, the protection resistor 10 has one end connected to the input terminal 1a and the other end connected to an anode of the first PIN diode 8. The first PIN diode 8 has a cathode connected to an anode of the second PIN diode 9 and the output terminal 1b respectively, whereas the second PIN diode 9 has a cathode connected to the ground terminal 1c. In the voltage shift circuit 2, the first resistor 11 has one end connected to the input terminal 2a and the other end connected to the output terminal 2b and one end of the second resistor 12 respectively. The second resistor 12 has the other end connected to a positive polarity terminal of the bias power supply 13. The bias power supply 13 has a negative polarity terminal connected to the ground terminal 2c. In the zener diode circuit 3, the zener diode 14 has a cathode connected to the input terminal 4a and an anode connected to the output terminal 3b and one end of the shunt resistor 15 respectively. The shunt resistor 15 has the other end connected to the ground terminal 3c.

In the weighting circuit 4, the first resistor 16 has one end connected to the input terminal 4a and the other end connected to the output terminal 4b and one end of the second resistor 17 respectively. The second resistor 17 has the other end connected to a positive polarity terminal of the bias power supply 18. The bias power supply 18 has a negative polarity terminal connected to the ground terminal 4c. In the adding circuit 5, the first adding resistor 20 has one end connected to the first input terminal 5a and the other end connected to a non-inversion input (+) of the amplifier 19. The second adding resistor 21 has one end connected to the second input terminal 5b and the other end connected to the non-inversion input (+) of the amplifier 19. The amplifier 19 has an output connected to the output terminal 5c and one end of the first feedback resistor 22 respectively, and an inversion input (−) connected to the other end of the first feedback resistor 22 and one end of the second feedback resistor 23 respectively. The second feedback resistor 23 has the other end connected to the ground terminal 5d.

In the variable resistance circuit based on the above configuration, the control voltage compensating circuit comprising the voltage shift circuit 2, the zener diode circuit 3, the weighting circuit 4 and the adding circuit 5 is connected to the input side of the PIN diode circuit 1 in such a manner that a change in RF resistance Ro between the RF resistance output terminals 7(1) and 7(2) with respect to a change in control voltage Vc inputted between the control voltage input terminals 6(1) and 6(2) is brought to a desired relation, i.e., the relationship between the change in control voltage Vc and the change in RF resistance Ro becomes approximately linear. The voltage shift circuit 2, the zener diode circuit 3, the weighting circuit 4 and the adding circuit 5 that constitute the control voltage compensating circuit are individually adjusted and set in such a manner that the response characteristic of the control voltage Vc shows such a characteristic as will next be described.

To begin with, a circuit configuration suitable as the PIN diode circuit 1 is equivalent to one which has the series-connected first PIN diode 8, the shunt-connected second PIN diode 9 and the series-connected protection resistor 10 and in which a high-frequency or RF resistance Rf is obtained between the RF resistance output terminal 7(1) connected to a connecting point of the first PIN diode 8 and the second PIN diode 9 and the ground-connected RF resistance output terminal 7(2). Viewing the inside of the PIN diode circuit 1 from between the RF resistance output terminals 7(1) and 7(2) where such a circuit configuration is adopted, the first PIN diode 8 and the second PIN diode 9 are placed in a state of being connected in parallel. Since a control voltage flows into the ground point through the first PIN diode 8 and the second PIN diode 9 when the control voltage is supplied to one end of the first PIN diode 8, the variable resistance circuit having such a characteristic that a resistance change width is not reduced, is obtained.

Incidentally, when the inside of the PIN diode circuit is viewed from between the two RF resistance output terminals where the PIN diode circuit is made up of one shunt-connected PIN diode and one series-connected protection resistor, the PIN diode and the protection resistor are connected in parallel and the control voltage supplied to one end of the protection resistor flows even into the protection resistor. Therefore, although such a characteristic that the resistance change width of the PIN diode is reduced correspondingly, is brought about, the compensating circuit may compensate for it inclusive of its reduction.

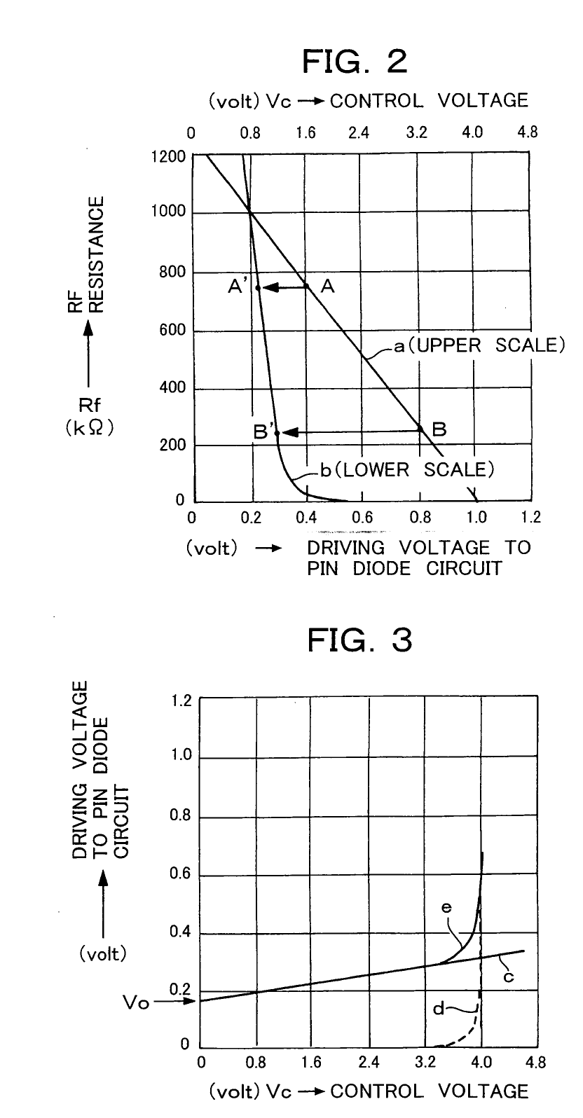

Now, FIG. 2 is a characteristic diagram showing, on a linear scale, the relationship between a control voltage Vc and an RF resistance Rf that the PIN diode circuit 1 shown in FIG. 1 assumes. A curve b indicates the relationship of an RF resistance Rf to a driving voltage applied to the PIN diode circuit 1. A curve a indicates a desired characteristic example that one desires to realize through the compensating circuit. The characteristic of the curve b is equivalent to one obtained when the PIN diode bar 64 manufactured by the S company is used for each of the first PIN diode 8 and the second PIN diode 9 and 500Ω is used for the protection resistor 10.

It is understood that as seen from the characteristic diagram illustrated in FIG. 2, the state of a change in the RF resistance Rf in the curve b results in a relatively steep change in the RF resistance Rf when the drive voltage changes within a range from 0 v to 0.4 v, whereas when the drive voltage changes within a range from 0.4 v to 1.0 v, the state thereof results in the fact that there is little change in the RF resistance Rf. On the other hand, if a change in the RF resistance Rf is brought into a linear change when, for example, the control voltage Vc changes within a range from 0 v to 4.0 v, then such a change is generally desirable because the operation of setting the RF resistance Rf by control on the control voltage Vc is brought to a state of being easiest to perform.

In order to obtain the characteristic having such a desired relation, the control voltage compensating circuit is connected to the PIN diode circuit 1, and the PIN diode circuit 1 may be driven via such a control voltage compensating circuit as to convert a control voltage Vc of 1.6 v to a voltage of about 0.23 v and convert a control voltage Vc of 3.2 v to a voltage of about 0.29 v in such a manner that the curve b is apparently seen as the curve a, specifically, when the applied control voltage Vc is 1.6 v, the RF resistance Rf at that time changes from the value of a point A on the curve a to the value of a point A′ on the curve b, whereas when the applied control voltage Vc is 3.2 v, the RF resistance Rf at that time changes from the value of a point B on the curve a to the value of a point B′ on the curve b.

The characteristic necessary for the present control voltage compensating circuit resides in that voltage compensation is brought about in such a manner that as described above, the output voltage of the compensating circuit becomes the value (about 0.23 v) of the point A′ when the control voltage Vc is of the value (1.6 v) of the point A, and similarly the output voltage thereof becomes the value (about 0.29 v) of the point B′ when the control voltage Vc is of the value (3.2 v) of the point B.

FIG. 3 is a characteristic diagram showing a voltage conversion state at the control voltage compensating circuit when voltage compensation for the PIN diode circuit is performed. The characteristic diagram shows that respective voltages obtained by two curves of a curve c and a curve d upon a change in control voltage Vc are added together to generate such an added voltage as indicated by a curve e. In this case, the curve c indicates a curve in which with an offset voltage V0 (about 0.17 v here) of the control voltage Vc as a starting point, a driving voltage for the PIN diode circuit increases linearly in proportional to an increase in control voltage Vc from the starting point as represented by a fine dot line. The curve d indicates a curve abruptly raised from the time when the control voltage Vc exceeds 3.2 v, as expressed by a coarse dot line. The curve e indicates a curve which follows the curve c until the control voltage Vc exceeds 3.2 v and principally follows the curve d when the control voltage Vc exceeds 3.2 v. Incidentally, as will be described later, the curve c is principally formed by the weighting circuit 4, and the curve d is principally formed by the zener diode circuit 3.

In this case, as expressed by the curve d illustrated in FIG. 3, the characteristic whose partial curvature becomes large can be brought into a characteristic approximation by utilizing the characteristic of a shoulder part transitioned from a saturated region of the zener diode 14 used in the zener diode circuit 3 to its breakdown region. Since the zener breakdown is used when the breakdown voltage of the zener diode is less than or equal to a few v, the zener diode is generally transitioned relatively gently from the saturated region to the breakdown region. Since, however, its avalanche breakdown is used when the breakdown voltage is more than or equal to a few v, the zener diode is suddenly transitioned from the saturated region to the breakdown region. Since various characteristics can be obtained according to differences in the structure of the zener diode and its manufacturing method as these characteristics of the zener diode, the corresponding zener diode nearest to a desired characteristic from these characteristics may be selected.

If the control voltage Vc is supplied to the PIN diode circuit 1 through the control voltage compensating circuit constituted of the voltage shift circuit 2, the zener diode circuit 3, the weighting circuit 4 and the adding circuit 5 in the present variable resistance circuit as described above, then such a variable resistance circuit that the change in the RF resistance Rf becomes approximately linear with respect to the change in the input control voltage Vc.

In this case, the control voltage compensating circuit is divided into two when the control voltage Vc is supplied to the control voltage input terminals 6(1) and 6(2). As the curve c illustrated in FIG. 3 is formed, the control voltage Vc applied to one of the control voltage input terminals is weighted by the weighting circuit 4 and then given the offset voltage V0, followed by being supplied to the adding circuit 5. As to the control voltage Vc supplied to the other thereof, the breakdown voltage of the zener diode 14 following the level shift circuit 2 is level-shifted so as to match with the curve d illustrated in FIG. 3 at the level shift circuit 2, and thereafter a pass current from the zener diode 14 is caused to lead as a voltage by a voltage drop developed across the shunt resistor 15 at the zener diode circuit 3. Such a voltage is supplied to the adding circuit 5. If the adding circuit 5 adds and amplifies the supplied two voltages and forms a control voltage Vc having such a characteristic as expressed in the curve e illustrated in FIG. 3, and supplies the formed control voltage Vc to the first PIN diode 8 and the second PIN diode 9 through the protection resistor 10, then such a variable resistance circuit as to indicate a desired change in RF resistance Rf with respect to a change in control voltage Vc is obtained.

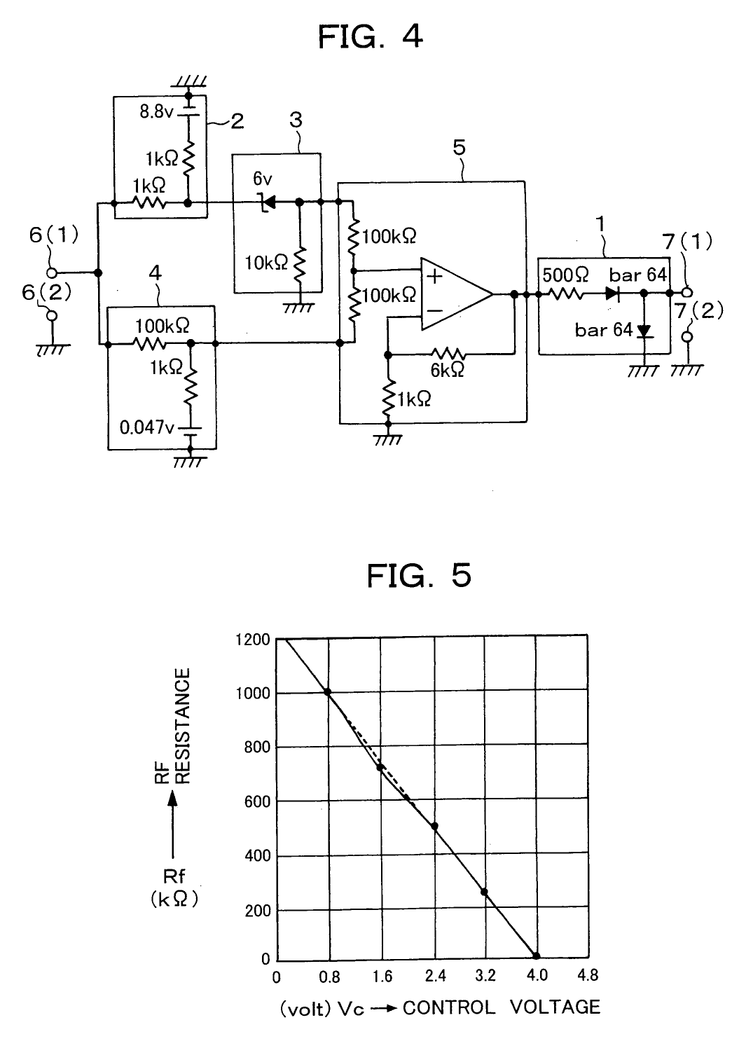

Now, FIG. 4 is a circuit diagram showing one example illustrative of suitable constants used for various constituent elements in the variable resistance circuit shown in FIG. 1. The circuit diagram shown in FIG. 4 includes substantially the same circuit configuration as that of the variable resistance circuit shown in FIG. 1. Incidentally, the same constituent elements as those shown in FIG. 1 are given the same reference numerals.

In the PIN diode 1 as shown in FIG. 4, the first PIN diode 8 and the second PIN diode 9 are both the PIN diode bar 64 manufactured by the S company, and the protection resistor 10 is a resistor of 500Ω. In the level shift circuit 2, the first resistor 11 and the second resistor 12 are both a resistor of 1 kΩ, and the bias battery 13 is a battery or power supply of 8.8 v. In the zener diode circuit 3, the zener diode 14 has a zener voltage of 6 v, and the shunt resistor 15 is a resistor of 10 kΩ. In the weighting circuit 4, the first resistor 16 is a resistor of 100 kΩ, the second resistor 17 is a resistor of 1 kΩ, and the bias battery 18 is a battery or power supply of 0.047 v. In the adding circuit 5, the first adding resistor 20 and the second adding resistor 21 are both a resistor of 100 kΩ, the first feedback resistor 22 is a resistor of 6 kΩ, and the second feedback resistor 23 is a resistor of 1 kΩ.

Next, FIG. 5 is a characteristic diagram showing the result of simulation run using the variable resistance circuit having the respective constants illustrated in FIG. 4. The characteristic diagram is represented along with the curve a illustrated in FIG. 2 for comparison. In the present figure, black circles and a solid line for connecting the respective black circles are ones obtained by simulation, and a line indicated by a fine dotted line corresponds to the curve a illustrated in FIG. 2 and is a line which indicates target values.

As shown in FIG. 5, the result of simulation approximately coincides with the line indicative of the target values except for a small proportion thereof. If the present variable resistance circuit is used, then the value of the RF resistance Rf obtained at the PIN diode circuit 1 comprising the first PIN diode 8 and the second PIN diode 9 can be made almost exactly inversely-proportional to a change in control voltage Vc apparently. Further, the value of the RF resistance Rf in the PIN diode circuit 1 can be easily set as desired by adjusting the control voltage Vc by a manual operation.

While the preferred form of the present invention has been described, it is to be understood that modifications will be apparent to those skilled in the art without departing from the spirit of the invention. The scope of the invention is to be determined solely by the following claims.

What is claimed is:

1. A variable resistance circuit, comprising:
a PIN diode circuit which adjusts a resistance value for PIN diodes according to the supply of a control voltage;
a voltage shift circuit which adds a shift voltage to the control voltage;
a zener diode circuit which applies a non-linear characteristic to a voltage outputted from the voltage shift circuit, using a zener characteristic of a zener diode;
a weighting circuit which applies a voltage offset to the control voltage; and
an adding circuit which adds respective voltages outputted from the zener diode circuit and the weighting circuit and supplies the so-added voltage to the PIN diode circuit,
wherein the shift voltage of the voltage shift circuit, the zener characteristic of the zener diode in the zener diode circuit and the voltage offset value of the weighting circuit are respectively selected and adjusted to set the RF resistance value for the PIN diodes in the PIN diode circuit so as to change approximately linearly with respect to a change in the control voltage.

2. The variable resistance circuit according to claim 1, wherein the PIN diode circuit has a configuration in which a first PIN diode used as a series element and a second PIN diode used as a shunt element are reversely L-connected to the same polarity.

3. The variable resistance circuit according to claim 1, wherein the voltage shift circuit has a configuration in which a first resistor used as a series element and a second resistor used as a shunt element are reversely L-connected and a bias power supply is series-connected to the second resistor.

4. The variable resistance circuit according to claim 1, wherein the zener diode circuit has a configuration in which a zener diode used as a series element and a resistor used as a shunt element are reversely L-connected.

5. The variable resistance circuit according to claim 1, wherein the adding circuit is provided with adding resistors and an amplifier.
